(19) United States
(12) Patent Application Publication
(10) Pub. No.: US 2026/0261260 A1
(43) Pub. Date: Sep. 3, 2026

(54) Cryogenic Actuator Controller

(71) Applicant: QphoX B.V., Delft (NL)

(72) Inventors: Frederick Mahmoud Hijazi, Delft (NL); Cristobal Ferrer, Delft (NL); Robert Hugh James Stockill, Delft (NL); Simon Groeblacher, Delft (NL)

(21) Appl. No.: 19/159,742

(22) PCT Filed: Feb. 26, 2024
(86) PCT No.: PCT/EP2024/054808

§ 371 Date: Aug. 26, 2025

(30) Foreign Application Priority Data
Feb. 27, 2023 (GB) 2302850.9

(51) Int. Cl. H03K 17/082; H03K 17/08

(52) U.S. Cl. CPC H03K 17/082; H03K 2017/0806; H03K 2217/0027; H03K 2217/0036

(57) ABSTRACT

A cryogenic actuator controller and a method for operating the cryogenic actuator controller is disclosed. The cryogenic actual controller may include a pulse generator, for generating a plurality of pulses, a feedback circuitry for measuring at least one of a power, a voltage, and/or a current of the plurality of pulses, at least one output stage for selecting one or more paths a plurality of paths and directing one or more pulses of the plurality of pulses to the one or more paths of the plurality of paths, at least one demultiplexer for controlling the at least one output stage, and/or a safety protection circuitry for monitoring and protecting a cryogenic load and one or more cryogenic components.

### CROSS-REFERENCE TO RELATED APPLICATIONS

This application is the United States national phase of International Patent Application No. PCT/EP2024/054808 filed Feb. 26, 2024, and claims priority to United Kingdom Patent Application No. 2302850.9 filed Feb. 27, 2023, the disclosures of each of which are hereby incorporated by reference in their entireties.

### BACKGROUND

### Field

The present disclosure relates to electronic control of actuators in a cryogenic environment and, in some on-limiting embodiments or aspects, to a system for electronic control of actuators in a cryogenic environment with reduced power dissipation by monitoring of an actuator state and using multiple protection mechanisms which reduce or prevent excessive heat loading of the cryogenic system.

### Description of Related Art

An increasing variety of microwave-frequency quantum technologies, ranging from superconducting and spin-based quantum computers to ultrasensitive detectors such as Kinetic inductance detector (KIDs), are emerging which operate at cryogenic (e.g., MilliKelvin or mK, etc.) temperatures with ultralow power signals in the single and few photon regime.

To reach sub-100 mK temperatures, dry and wet 3He/4He dilution refrigerators, 3He cryostats, or adiabatic demagnetization refrigerators are commonly employed. However, the cooling power at the lowest temperatures may be limited. To reach and maintain these cryogenic temperatures, careful thermal management, and restricting unnecessary power dissipation of both passive and active components may be employed.

Thermal constraints, together with spatial limitations and long cycling times have motivated the use of many-way Multiple-Pole Multiple-Throw (nPnT) microwave frequency cryogenic switches. These switches allow multiplexing of cryogenic microwave lines. While solid state switches offer ultralow power control compatible with the cooling power constraints of the cryostat, their working temperature range is often limited to ~4K and insertion losses are typically prohibitively high.

Therefore, mechanically based actuators are commonly employed in the prior art for ultralow signal level cryogenic switching applications. However, the power requirements for mechanically actuating microwave frequency cryogenic switches is, generally, of the order of several Watts, which is much higher than the cooling power provided at the mK stages on which the microwave frequency cryogenic switches are installed. This cooling power can be as low as a few μW.

A single actuation event can result in substantial heat dissipation, raising base-plate temperatures to levels that require several hours to return to equilibrium temperature, causing measurements and device operation to be paused until the base equilibrium temperature is regained.

Existing superconducting modified actuators may allow for lower power dissipation. However, these improvements still produce considerable heat dissipation.

### SUMMARY

As power levels used for mechanical actuation are orders of magnitude larger than a continuous cooling power provided by a cryostat, an actuator controller may employ energy controlling or limiting mechanisms to avoid accidental damage to the cryostat and/or disruption of measurements. Non-limiting embodiments or aspects of the present disclosure may provide energy controlling or limiting mechanisms that have been tested with a variety of cryogenic actuators and cryogenic setups which are capable of actuating with sub-mK heating of the relevant operating environment, for example, of dilution refrigerator baseplate.

Non-limiting embodiments or aspects of the present disclosure may enable improving or optimizing properties of control signals and power pulses transmitted to cryogenic actuators to reduce or minimize power dissipation in the cryogenic environment.

According to some non-limiting embodiments or aspects, provided is a cryogenic actuator controller including: a pulse generator configured to generate a plurality of pulses; a feedback circuitry configured to measure and control at least one of a power of the plurality of pulses, a voltage of the plurality of pulses, a current of the plurality of pulses, or any combination thereof; at least one output stage configured to select one or more paths of a plurality of paths and direct one or more pulses of the plurality of pulses to the one or more paths of the plurality of paths; at least one demultiplexer configured to control the at least one output stage; and a safety protection circuitry configured to monitor and protect a cryogenic load and one or more cryogenic components.

In some non-limiting embodiments or aspects, the pulse generator is configured to generate the plurality of pulses as a plurality of energy-limited pulses by controlling at least one of the voltage of the plurality of pulses, the current of the plurality of pulses, a duration of the plurality of pulses, a frequency of the plurality of pulses, or any combination thereof.

In some non-limiting embodiments or aspects, the feedback circuitry is configured to determine a state of the cryogenic actuator based on features of a measured waveform associated with the plurality of pulses.

In some non-limiting embodiments or aspects, the pulse generator is configured to control an energy level of the plurality of pulses independent of an impedance of the cryogenic load.

In some non-limiting embodiments or aspects, the safety protection circuitry is configured to monitor at least one of an output voltage of the plurality of the pulses, an output current of the plurality of the pulses, a pulse waveform duration of the plurality of the pulses of the plurality of the pulses, or any combination thereof.

In some non-limiting embodiments or aspects, the safety protection circuitry includes one or more independent sections.

In some non-limiting embodiments or aspects, the at least one output stage is configured to dynamically and independently select the one or more paths of the plurality of paths for the one or more pulses of the plurality of pulses to be delivered to the cryogenic load.

According to some non-limiting embodiments or aspects, provided is a method for controlling a level of energy input to a cryogenic load including: generating a plurality of pulses of electrical energy; monitoring at least one of a power of the plurality of pulses, a voltage of the plurality of pulses, a current of the plurality of pulses, or any combination thereof; selecting one or more paths of a plurality of paths to provide one or more pulses of the plurality of pulses to one or more cryogenic loads of a plurality of cryogenic loads in a cryostat; and monitoring the one or more cryogenic loads of the plurality of cryogenic loads and one or more cryogenic components of the cryostat.

In some non-limiting embodiments or aspects, the method further includes: dynamically modulating one or more of an applied current of the plurality of pulses, an applied voltage of the plurality of pulses, or any combination thereof to obtain a given pulse waveform.

In some non-limiting embodiments or aspects, the one or more paths of the plurality of paths are dynamically and independently selected.

In some non-limiting embodiments or aspects, selecting the one or more paths of the plurality of paths supplies different pulses of the plurality of pulses to different loads of the plurality of cryogenic loads.

In some non-limiting embodiments or aspects, the method further includes: recording a pulse of the plurality of pulses to enable a dynamic state estimation of the cryogenic load.

In some non-limiting embodiments or aspects, the method further includes: computing and controlling the level of energy delivered to the cryogenic load.

In some non-limiting embodiments or aspects, the method further includes: controlling the energy delivered to the cryogenic load to control an amount of power dissipated inside the cryostat.

Non-limiting embodiments or aspects of the present disclosure may provide systems and methods for improving or optimizing properties of control signals and power pulses transmitted to cryogenic actuators to reduce or minimize power dissipation in the cryogenic environment. A system may include a power-limiting pulse waveform generator, a logic processing unit for configuring and controlling the power output stages, a power amplification stage, feedback circuitry for monitoring and optimizing output pulse waveforms, and an independent safety monitoring system to inhibit or prevent extraneous power dissipation and damage to connected devices.

Further non-limiting embodiments or aspects are set forth in the following numbered clauses:

Clause 1: A cryogenic actuator controller comprising: a pulse generator configured to generate a plurality of pulses; a feedback circuitry configured to measure and control at least one of a power of the plurality of pulses, a voltage of the plurality of pulses, a current of the plurality of pulses, or any combination thereof; at least one output stage configured to select one or more paths of a plurality of paths and direct one or more pulses of the plurality of pulses to the one or more paths of the plurality of paths; at least one demultiplexer configured to control the at least one output stage; and a safety protection circuitry configured to monitor and protect a cryogenic load and one or more cryogenic components.

Clause 2: The cryogenic actuator controller of clause 1, wherein the pulse generator is configured to generate the plurality of pulses as a plurality of energy-limited pulses by controlling at least one of the voltage of the plurality of pulses, the current of the plurality of pulses, a duration of the plurality of pulses, a frequency of the plurality of pulses, or any combination thereof.

Clause 3: The cryogenic actuator controller of clause 1 or 2, wherein the feedback circuitry is configured to determine a state of the cryogenic actuator based on features of a measured waveform associated with the plurality of pulses.

Clause 4: The cryogenic actuator controller of any of clauses 1-3, wherein the pulse generator is configured to control an energy level of the plurality of pulses independent of an impedance of the cryogenic load.

Clause 5: The cryogenic actuator controller of any of clauses 1-4, wherein the safety protection circuitry is configured to monitor at least one of an output voltage of the plurality of the pulses, an output current of the plurality of the pulses, a pulse waveform duration of the plurality of the pulses of the plurality of the pulses, or any combination thereof.

Clause 6: The cryogenic actuator controller of any of clauses 1-5, wherein the safety protection circuitry includes one or more independent sections.

Clause 7: The cryogenic actuator controller of any of clauses 1-6, wherein the at least one output stage is configured to dynamically and independently select the one or more paths of the plurality of paths for the one or more pulses of the plurality of pulses to be delivered to the cryogenic load.

Clause 8: A method for controlling a level of energy input to a cryogenic load comprising: generating a plurality of pulses of electrical energy; monitoring at least one of a power of the plurality of pulses, a voltage of the plurality of pulses, a current of the plurality of pulses, or any combination thereof; selecting one or more paths of a plurality of paths to provide one or more pulses of the plurality of pulses to one or more cryogenic loads of a plurality of cryogenic loads in a cryostat; and monitoring the one or more cryogenic loads of the plurality of cryogenic loads and one or more cryogenic components of the cryostat.

Clause 9: The method of clause 8, further comprising: dynamically modulating one or more of an applied current of the plurality of pulses, an applied voltage of the plurality of pulses, or any combination thereof to obtain a given pulse waveform.

Clause 10: The method of clause 8 or 9, wherein the one or more paths of the plurality of paths are dynamically and independently selected.

Clause 11: The method of any of clauses 8-10, wherein selecting the one or more paths of the plurality of paths supplies different pulses of the plurality of pulses to different loads of the plurality of cryogenic loads.

Clause 12: The method of any of clauses 8-11, further comprising: recording a pulse of the plurality of pulses to enable a dynamic state estimation of the cryogenic load.

Clause 13: The method of any of clauses 8-12, further comprising: computing and controlling the level of energy delivered to the cryogenic load.

Clause 14: The method of any of clauses 8-113, further comprising: controlling the energy delivered to the cryogenic load to control an amount of power dissipated inside the cryostat.

These and other features and characteristics of the presently disclosed subject matter, as well as the methods of operation and functions of the related elements of structures and the combination of parts and economies of manufacture, will become more apparent upon consideration of the following description and the appended claims with reference to the accompanying drawings, all of which form a part of this specification. It is to be expressly understood, however, that the drawings are for the purpose of illustration and description only and are not intended as a definition of the limits of the disclosed subject matter. As used in the specification and the claims, the singular form of “a,” “an,” and “the” include plural referents unless the context clearly dictates otherwise.

### BRIEF DESCRIPTION OF THE DRAWINGS

Additional advantages and details are explained in greater detail below with reference to the non-limiting, exemplary embodiments that are illustrated in the accompanying schematic figures, in which:

FIG. 1 shows a cryogenic actuator controller, according to some non-limiting embodiments or aspects;

FIG. 2 shows example measured pulse waveforms under various drive and load conditions, according to some non-limiting embodiments or aspects;

FIG. 3 shows a characteristic signal waveform of mechanical actuator switching, according to some non-limiting embodiments or aspects;

FIG. 4 shows an internal operation of a single output stage, according to some non-limiting embodiments or aspects;

FIG. 5 shows an operation of an output stage for rerouting a pulse path, according to some non-limiting embodiments or aspects; and

FIG. 6 shows a flow diagram of a method of controlling a cryogenic actuator, according to some non-limiting embodiments or aspects.

### DESCRIPTION

For purposes of the description hereinafter, the terms “end,” “upper,” “lower,” “right,” “left,” “vertical,” “horizontal,” “top,” “bottom,” “lateral,” “longitudinal,” and derivatives thereof shall relate to the embodiments as they are oriented in the drawing figures. However, it is to be understood that the present disclosure may assume various alternative variations and step sequences, except where expressly specified to the contrary. It is also to be understood that the specific devices and processes illustrated in the attached drawings, and described in the following specification, are simply exemplary and non-limiting embodiments or aspects of the disclosed subject matter. Hence, specific dimensions and other physical characteristics related to the embodiments or aspects disclosed herein are not to be considered as limiting.

Some non-limiting embodiments or aspects are described herein in connection with thresholds (e.g., safety conditions, etc.). As used herein, satisfying a threshold may refer to a value being greater than the threshold, more than the threshold, higher than the threshold, greater than or equal to the threshold, less than the threshold, fewer than the threshold, lower than the threshold, less than or equal to the threshold, equal to the threshold, etc.

No aspect, component, element, structure, act, step, function, instruction, and/or the like used herein should be construed as critical or essential unless explicitly described as such. Also, as used herein, the articles “a” and “an” are intended to include one or more items and may be used interchangeably with “one or more” and “at least one.” Furthermore, as used herein, the term “set” is intended to include one or more items (e.g., related items, unrelated items, a combination of related and unrelated items, and/or the like) and may be used interchangeably with “one or more” or “at least one.” Where only one item is intended, the term “one” or similar language is used. Also, as used herein, the terms “has,” “have,” “having,” or the like are intended to be open-ended terms. Further, the phrase “based on” is intended to mean “based at least partially on” unless explicitly stated otherwise. In addition, reference to an action being “based on” a condition may refer to the action being “in response to” the condition. For example, the phrases “based on” and “in response to” may, in some non-limiting embodiments or aspects, refer to a condition for automatically triggering an action (e.g., a specific operation of an electronic device, such as a computing device, a processor, and/or the like).

As used herein, the term “communication” may refer to the reception, receipt, transmission, transfer, provision, and/or the like of data (e.g., information, signals, messages, instructions, commands, and/or the like). For one unit (e.g., a device, a system, a component of a device or system, combinations thereof, and/or the like) to be in communication with another unit means that the one unit is able to directly or indirectly receive information from and/or transmit information to the other unit. This may refer to a direct or indirect connection (e.g., a direct communication connection, an indirect communication connection, and/or the like) that is wired and/or wireless in nature. Additionally, two units may be in communication with each other even though the information transmitted may be modified, processed, relayed, and/or routed between the first and second unit. For example, a first unit may be in communication with a second unit even though the first unit passively receives information and does not actively transmit information to the second unit. As another example, a first unit may be in communication with a second unit if at least one intermediary unit processes information received from the first unit and communicates the processed information to the second unit. In some non-limiting embodiments or aspects, a message may refer to a network packet (e.g., a data packet and/or the like) that includes data. It will be appreciated that numerous other arrangements are possible.

As used herein, the term “computing device” may refer to one or more electronic devices configured to process data. A computing device may, in some examples, include the necessary components to receive, process, and output data, such as a processor, a display, a memory, an input device, a network interface, and/or the like. A computing device may be a mobile device. As an example, a mobile device may include a cellular phone (e.g., a smartphone or standard cellular phone), a portable computer, a wearable device (e.g., watches, glasses, lenses, clothing, and/or the like), a personal digital assistant (PDA), and/or other like devices. A computing device may also be a desktop computer or other form of non-mobile computer.

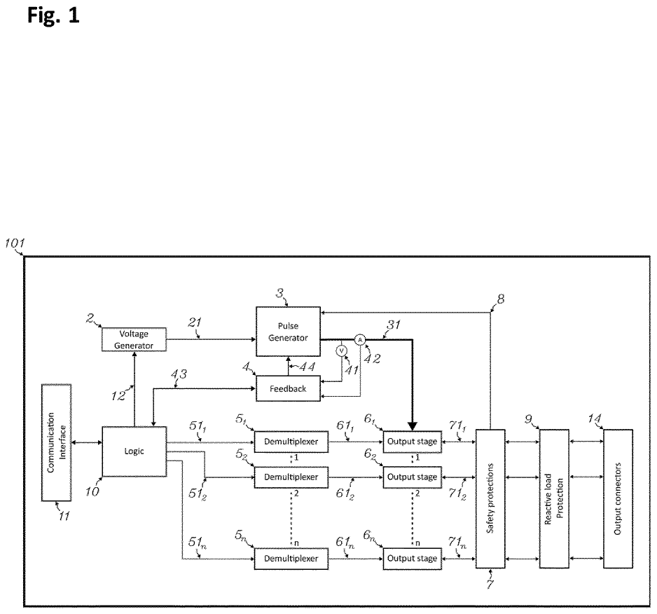

FIG. 1 shows a cryogenic actuator controller 101 which may include a logic processing unit 10, a pulse generator 3, a feedback circuitry 4, at least one output stage 6, a demultiplexer 5, a monitoring circuitry 7, a load protection system 9, and/or output connectors 14. The pulse generator 3 and/or the feedback circuitry 4 may generate a plurality of pulses 31, for example, a plurality of programmable waveform pulses 31.

The monitoring circuity 7 may correspond to the safety protections or safety protection circuitry. The load protection system 9 may be referred to as a reactive load protection system. It is noted that throughout the present disclosure, a cryogenic actuator may be referred to as load or a cryogenic load.

For example, a cryogenic actuator controller 101 may include a pulse generator 3 configured to generate a plurality of pulses 31, a feedback circuitry 4 configured to measure and control at least one of a power of the plurality of pulses 31, a voltage of the plurality of pulses 31, a current of the plurality of pulses 31, or any combination thereof, at least one output stage 6 configured to select one or more paths of a plurality of paths 71₁ to 71ₙ and direct one or more pulses of the plurality of pulses 31 to the one or more paths plurality of paths 71₁ to 71ₙ, at least one demultiplexer 5 configured to control at least one output stage 6, and/or a safety protection circuitry 7 configured to monitor and protect a cryogenic load. In some implementations, cryogenic components surrounding the cryogenic load may be protected. The safety criteria may be set by the other components in the cryostat, for example, by controlling or requiring that the cryostat remains at a set temperature or the like. A plurality of pulses refers to different pulses in time. For example, two pulses out of the plurality of pulses are separated in time.

The logic processing unit 10 controls the demultiplexer 5. The demultiplexer 5 provides dynamic reconfigurability of the output stage 6. In some implementations, the cryogenic actuator controller 101 may include a plurality of the demultiplexers 5₁ to 5ₙ, which may be used to control a plurality of output stages 6₁ to 6ₙ through selection lines 61₁ to 61ₙ, thus selecting the path and direction of the power pulse 31.

For example, the demultiplexer 5 may be configured to control an output stage 6. As exemplarily shown in FIG. 1, each demultiplexer 5; out of the plurality of demultiplexers 5₁ to 5ₙ may control a respective output stage 6ᵢ, where i is an integer from 1 to n.

For example, in a system with one load, two output stages may be controlled to direct the pulse to a path connected to the load. In such an exemplary implementation, the return path may be implemented with one of those two output stages. However, the return path may be implemented without using an output stage. For each additional load, one additional output stage may be controlled to direct the pulse to a path connected to a respective load, because a re-use of one of the other paths (and, for example, a corresponding output stage) may be possible.

Each of the plurality of the output stages 6₁ to 6ₙ may share the same pulse 31. By applying the corresponding logic to the demultiplexers 5₁ to 5ₙ, the path of each pulse 31 can therefore be reconfigured.

For example, each pulse 31 may be dynamically re-directed to exit through any of lines 71₁ to 71ₙ and thus to different loads. The path and a direction is selected by the output stage, which in turn is configured by the demultiplexer. Such a selection is performed by the demultiplexer. The logic for performing a selection is based on the desired path and/or current direction. Each load is connected to at least two paths, but paths may be shared between different loads.

When the power pulse 31 reaches each of the output stages 6₁ to 6ₙ, the logic processing unit 10 determines whether the pulse 31 is directed to the safety protection circuitry 7 by the lines 71₁ to 71ₙ or whether the pulse 31 is ignored. Directing the pulse 31 enables a single pulse 31 to be used by multiple outputs. The pulses 31 which satisfy the safety criteria imposed by the safety protection circuitry 7 (e.g., monitoring circuitry, etc.) may exit the cryogenic actuator controller via output connectors 14 to the cryogenic load.

In general, directing the pulse 31 enables a single pulse 31 to be used either by multiple outputs, one output, or none.

Such a cryogenic load may be, for example, a solenoid actuator, a cryogenic actuator, or a series or network of such elements.

The reactive load protection system 9 can be placed, for example, between the safety protection circuitry 7 and the output connectors 14. The reactive load protection system 9 may be used to protect the controller 101 from damaging electromagnetic forces generated by large reactive loads.

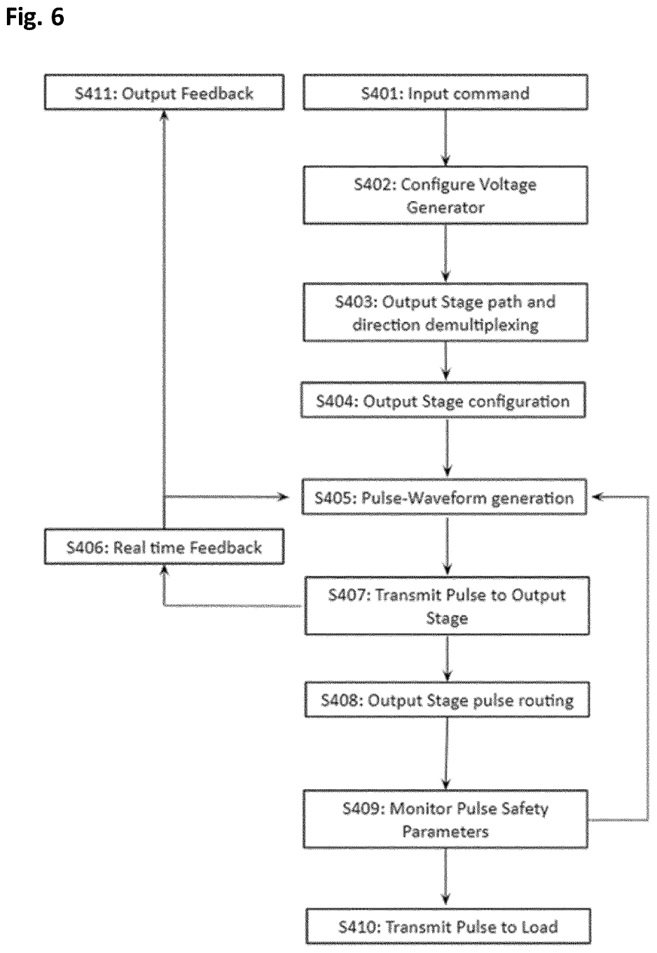

At least one output stage 6 may be reconfigurable and operable to select one or more paths or directions for the power pulse to be delivered to the cryogenic load. The selection process is further explained in step S403 with respect to FIG. 6 below. The selection may be performed based on the specific load to which the pulse is to be directed. For example, the output stage may be dynamically reconfigured (e.g., controlled, etc.) by a software to select the output path and return path.

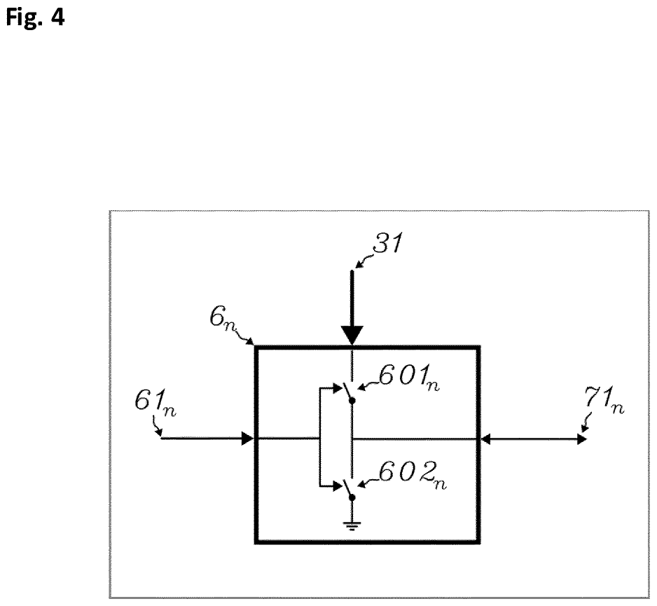

FIG. 4 shows an internal operation of an output stage 6ₙ. The common line 71ₙ can be either connected to the pulse line 31 by closing the switch 601ₙ, to a shared ground by closing 602ₙ, or left floating if each of switches 601ₙ and 602ₙ are left open. The switches 601ₙ and 602ₙ can be implemented as field-effect transistor (FET), bipolar junction transistor (BJT) or any other kind of solid-state devices.

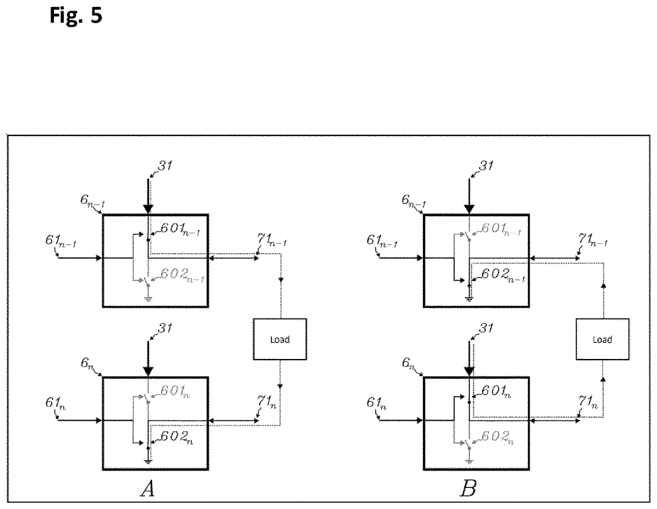

FIG. 5 illustrates an operation of an output stage 6 for rerouting the pulse path and direction, the output protections and monitoring are omitted for clarity. In 610-A of FIG. 5 the upper switch 601ₙ₋₁ is closed, redirecting the pulse 31 to the load. The pulse 31 pass through the load and is redirected again by closing a switch 602ₙ. In 610-B the inverted configuration is used, thus maintaining the pulse path but inverting the polarity.

An inverting of the polarity corresponds to an inverting of the direction of the pulse. For example, in 610-B of FIG. 5 the upper switch 601ₙ is closed, redirecting the pulse 31 to the load. The pulse 31 passes through the load and is redirected again, on the return path, by closing a switch 602ₙ₋₁.

Since the pulse direction can be inverted by every output stage 6₁ to 6ₙ, the pulse path and pulse direction can be selected by choosing a state of switches 601ₙ and 602ₙ for the output stage 6ₙ.

For example, the pulse path and pulse direction, sent to the cryogenic load, may be selected by choosing a state of switches 601ₙ and 602ₙ for every output stage 6ₙ.

The pulse generator 3 is configured to generate a plurality of pulses 31. The pulse generator 3 may generate the plurality of pulses as a plurality of energy-limited pulses 31 by restricting at least one of a voltage of the plurality of pulses, a current of the plurality of pulses, a duration of the plurality of pulses, a frequency of the plurality of pulses 31. Such an energy-limited pulse may be based on a feedback signal from the feedback circuitry 4. For example, a pulse out of the plurality of energy-limited pulses 31 may be obtained by controlling or restricting at least one of a voltage, a current, a duration, a frequency, or any combination thereof of said pulse.

The pulse generator 3 may control the energy of the plurality of pulses 31 independent of the impedance of the cryogenic load. Impedance of cryogenic loads changes drastically with temperature, thus by controlling the voltage, the current, the duration, the frequency or any combination thereof, the controller ensures that the same amount of energy is delivered to the cryogenic load, disregarding the impedance of the cryogenic load.

The pulse generator 3 together with the feedback circuitry 4 may be used to generate the programmable waveform pulse 31. The feedback network 4 comprises at least three inputs. The pulse voltage 41 and a pulse current 42 may be measured at first and second inputs of the feedback circuitry or network 4. The third input of the feedback circuitry or network 4 is a timing signal produced by the logic processing unit 10, which may be fed by a communication bus 43.

For example, the first two inputs may include the pulse voltage 41 and the pulse current 42, which are measured by the feedback circuitry 4 (e.g., a feedback network, etc.).

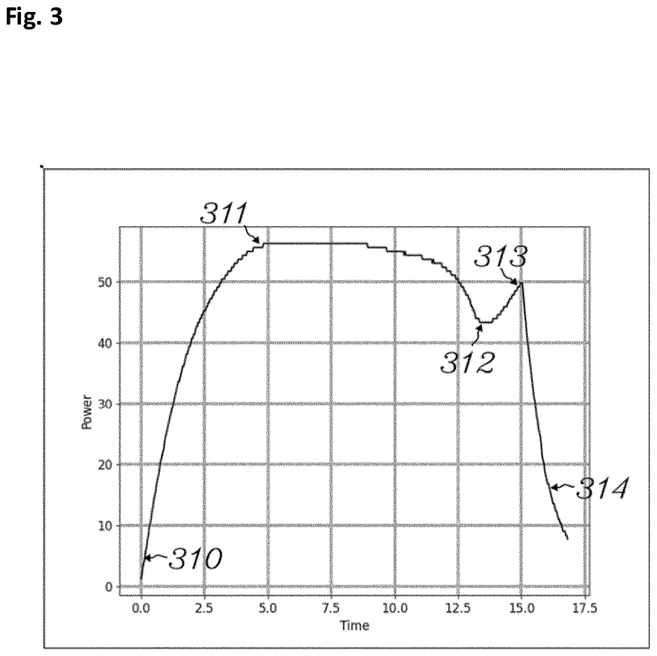

The feedback circuitry 4 may compute a feedback signal 44 and pass the feedback signal 44 to the pulse generator 3. FIG. 3 shows a signal waveform of the pulse current 42 delivered to the load. Dynamics of the actuator monitored in real time, by the feedback circuitry 4, enable improving or optimizing a minimum amount of power that is to be delivered to the actuator in order to engage the desired state.

For example, dynamics of the load may be monitored in real time by the feedback circuitry 4. Such monitoring enables adapting an amount of power that is to be delivered, to the load, to successfully engage the desired state.

In the example waveform, real time feedback may enable predictive determination of the actuator state based on features 310 to 314 of the waveform shown in FIG. 3. Predictive estimation of the actuator state may enable early termination of the waveform and thereby reduction in power dissipation.

In a non-limiting way and using FIG. 3 as an example for the pulse waveform, feature 310 indicates a beginning of the pulse. A slope of the power waveform between features 310 and 311, as well as a maximum power 311, may be used to determine the cryogenic load characteristics. Feature 312 shows a dip in power associated with a cryogenic load successful engagement, such as, for example, an actuator reaching its final position. Once the load has been successfully engaged at 312, there may be some time lapse 313 until the end of the pulse 314. As mentioned earlier, the early termination of the pulse, and therefore the reduction or minimization of 313, facilitates reducing power dissipated inside the cryostat by the cryogenic load.

In the example of FIG. 3, the power is given in units of microwatts, and the time is given in units of milliseconds. However, non-limiting embodiments or aspects of the present disclosure are not limited to these exemplary magnitudes. In general, the units of power and time may depend on the characteristics of the load.

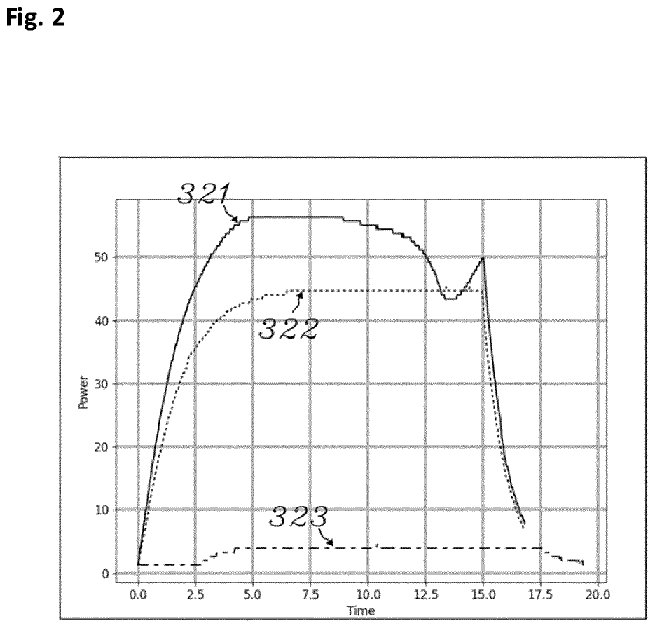

In some implementations, the feedback signal 44 may be transmitted via the communication bus 43 to the logic processing unit 10 and the feedback signal 44 may be transmitted via the communication interface 11 externally for diagnostic or recording purposes (e.g., to an external computing device, etc.). FIG. 2 shows three pulse waveforms, two of which may be used to diagnose problems related to the load network. As an example, 322 and 323 lack the distinctive features 310 to 314 displayed on 321.

For example, a pulse that does not provide sufficient power to engage the cryogenic load may show, as an example, waveforms 322 and 323. These waveforms lack the distinctive features 310 to 314 displayed on FIG. 3. For example, FIG. 2 shows measured pulse waveforms under various pulse powers and load impedances.

The feedback waveform produced by the feedback circuitry 4 may be used to determine the state of the cryogenic load based on the features of said waveform, such as features 310 to 314 mentioned earlier with respect to FIG. 3. Such features may include the beginning of the pulse 310, the slope between the beginning of the pulse 310 and the maximum power 311, the maximum power 311, the characteristic dip in power 312, and/or the like.

The adjustable voltage generator 2 may be used by the pulse generator 3 as a source to produce the power pulse 31. The generated voltage may be controlled with the control line 12 by the logic processing unit 10.

The safety protection circuitry 7 may be used to monitor and protect each of the load and one or more cryogenic components connected electrically or thermally to the load from possible circuit failures and/or user errors. A communication line 8 may be used by the safety protection 7 to shut down the pulse generator 3 in case the voltage, the current, or the time exceed the safety conditions. The safety protection circuitry 7 may operate independently from the rest of the system and provide a third layer of fail-safe redundancy and/or software layer protection, separate from the feedback network 4. In one aspect, the safety protection circuitry 7 comprises a plurality of isolated circuitries that enable the safety protection circuit 7 to continue operating even when other parts of the circuitry fail.

Such cryogenic components may surround the cryogenic load connected to the controller 101. For example, the cryogenic components may include other systems cooled down in the cryostat. The cryogenic components may include, for example, one or more of the following: a quantum processor, a cryogenic amplifier, an electro-optic transducer, a superconducting nanowire single photon detector, a superconducting system including at least one superconducting coil, samples that are being tested in the cryostat, components that form the cryostat itself, or any combination thereof.

The safety protection circuitry 7 may monitor at least one of the output voltage of the plurality of the pulses 31, the output current of the plurality of the pulses 31, the pulse waveform duration of the plurality of the pulses 31, or any combination thereof. The safety protection circuitry 7 may correspond to an independent monitoring circuitry. The safety protection circuitry 7 may comprise one or a plurality of independent (e.g., isolated, etc.) sections. As mentioned above, two pulses out of the plurality of pulses are separated in time. Thus, the safety protection circuitry 7 may monitor at least one of the output voltage, the output current, and the pulse waveform duration of a pulse out of the plurality of the pulses.

The safety protection circuitry 7 may measure the voltage, the current, and/or the time per path 71. For example, for each path 71, the safety protection circuitry 7 may measure one or more of the voltage, the current, and/or the time. The safety protection circuitry 7 may compare one or more of the measured values to safety conditions. The safety conditions may be based on the characteristics of the load to be driven.

In some implementations, a cryogenic actuator controller 101 may comprise a pulse generator 3 configured to generate a pulse 31. A feedback circuitry 4 may be included in the cryogenic actuator controller 101 for measuring at least one of a power of the pulse 31, a voltage of the pulse 31, a current of the pulse 31, or any combination thereof and generating a feedback signal for passing to the pulse generator. The cryogenic actuator controller 101 may further comprise at least one output stage 6₁ to 6ₙ, each of the at least one output stages may be connected to a respective path out of a plurality of paths 71₁ to 71ₙ, each of the at least one output stages 6₁ to 6ₙ may be controllable to direct the pulse from the pulse generator 3 to the respective path. The cryogenic actuator controller 101 may further comprise at least one demultiplexer 5₁ to 5ₙ. Each of the at least one demultiplexers 5₁ to 5ₙ may be configured to control a respective one of the at least one output stages 6₁ to 6ₙ. A safety protection circuitry 7 may be included in the cryogenic actuator controller 101 for monitoring and protecting a cryogenic load, wherein each path out of the plurality of paths 71₁ to 71ₙ is connected to the safety protection circuitry 7, the safety protection circuitry 7 configured to shut down the pulse generator 3 when a voltage of the pulse, a current of the pulse, a time of the pulse, or any combination thereof exceeds safety conditions and to output the pulse when the safety conditions are satisfied.

In correspondence with the above-described cryogenic actuator controller, a method for controlling the level of energy delivered to a cryogenic load is provided.

A method for controlling the level of energy delivered to a cryogenic load may include:
generating a plurality of pulses 31 of electrical energy;
monitoring at least one of a power of the plurality of pulses 31, a voltage of the plurality of pulses 31, a current of the plurality of pulses 31, or any combination thereof;
selecting one or more paths of a plurality of paths 71₁ to 71ₙ to provide one or more pulses of the plurality of pulses 31 to one or more cryogenic loads of a plurality of loads in the cryostat; and
monitoring the one or more cryogenic loads of the plurality of cryogenic loads and one or more cryogenic components of the cryostat.

Energy input to the cryogenic load, such as an actuator, may correspond to energy delivered to said load via the selected one or more paths of the plurality of paths 71₁ to 71ₙ. The monitoring of the cryogenic load may include a monitoring of the state of the cryogenic load. For example, such a monitoring may be based on features of the waveform of the pulse, as explained above.

For example, the method may comprise generating a pulse of electrical energy, monitoring at least one of a power of the pulse 31, a voltage of the pulse 31, a current of the pulse 31, or any combination thereof, selecting one or more paths of a plurality of paths 71₁ to 71ₙ to provide the pulse 31 to a load in the cryostat; and/or monitoring a state of the cryogenic load.

The method may be performed by the cryogenic actuator controller 101, which is explained in detail above. For example, a pulse may be generated by a pulse generator. At least one output stage may be controlled by at least one demultiplexer, respectively, to direct the pulse from the pulse generator to a path connected to an respective output stage. The method may further comprise monitoring and protecting a cryogenic load by a safety protection circuit 7, wherein each path out of the plurality of paths 71₁ to 71ₙ is connected to the safety protection circuitry 7, the safety protection circuitry 7 being configured to shut down the pulse generator 3 when a voltage of the pulse, a current of the pulse, a time of the pulse, or any combination thereof exceeds safety conditions, and to output the pulse when the safety conditions are satisfied.

The controlling of the level of energy input (e.g., delivered, etc.) to the cryogenic load may further comprise dynamically modulating one or more of the applied current 42 or the applied voltage 41 of one of the plurality of pulses 31 within a given pulse waveform.

The selecting of the one or more of the plurality of paths 71₁ to 71ₙ may be dynamic and independently selectable. Such a selection may be a selection as performed by an output section 6 as explained above, for example, with reference to FIGS. 4 and 5.

The selecting of the one or more of the plurality of paths 71₁ to 71ₙ may enable different ones of the pulses 31 to be supplied to different ones of the loads.

For example, in a system with one load, two output stages may be controlled to direct the pulse to a path connected to the load. For each additional load, one additional output stage may be controlled to direct the pulse to a path connected to a respective load, since a re-use one of the other paths (and, for example, a corresponding output stage) may be possible. Thus, by selecting a first path of the plurality of paths 71₁ to 71ₙ, a first pulse may be supplied to a load connected to the first path. A second pulse out of the plurality of pulses may be supplied to a load connected to a second path by selecting said second path. The load connected to the first path may be different from the load connected to the second path.

The method for controlling a level of energy input (e.g., delivered, etc.) to a cryogenic load may further include recording a pulse of the plurality of pulses 31 to enable dynamic state estimation of the actuator. For example, a pulse out of the plurality of pulses 31 may be measured by the feedback circuitry 4 and further transmitted through communication bus 43 to the logic unit 10, and to the communication interface 11 for recording purposes. Based on such a recording, a state of a load may be estimated.

The method for controlling a level of energy input (e.g., delivered, etc.) to a cryogenic load may further include computing a level or an amount energy delivered to the cryogenic load. The method for controlling the level or the amount of energy delivered to a cryogenic load may further include computing and controlling the level or the amount of energy delivered to the cryogenic load. The method for controlling the level or the amount of energy delivered to a cryogenic load may further include acquiring, computing, and controlling the voltage of the pulse 31, the current of the pulse 31, the duration of the pulse 31, the frequency of the pulse 31, or any combination thereof.

The method for controlling the level of energy input to a cryogenic load may further include controlling or limiting the energy delivered to the cryostat for controlling or limiting the power delivered to the cryostat. Such a limitation may be obtained by controlling or restricting at least one of a voltage, a current, a duration, and/or a frequency of the plurality of energy-limited pulses. For example, the level of energy delivered to the cryogenic load may be controlled. Controlling or limiting the energy delivered to the cryogenic load may facilitate controlling or limiting the power dissipated inside the cryostat.

FIG. 6 shows a flow diagram for a method of controlling a cryogenic actuator, according to some non-limiting embodiments or aspects. In some implementations, the actuator can be an electromechanical element, for example, a solenoid actuator, a cryogenic actuator, or a series or network of such elements. it is noted that the actuation mechanism is not limited to electromechanical systems, but may also be a thermal or a semiconductor-based switch.

The example of FIG. 6 is not limited to cryogenic actuators, but may also be applied to any cryogenic load.

In step S401, the input command carries the information needed for setting up the controller. Either path and direction, pulse, or waveform commands can be sent to control the overall system.

For example, either path, direction, pulse, or waveform information may be sent either through commands or other communication methods to control the overall system.

In step S402, the voltage generator 2 is configured to provide sufficient voltage headroom for the pulse generator operation. The generated voltage 21 is computed based on the desired pulse waveform shape.

The desired pulse waveform shape in turn is determined by the desired current and load impedance.

In step S403, the demultiplexer 5 interprets and configures the plurality of the output stages 6₁ to 6ₙ to the appropriate state, depending on the desired pulse path and direction This results in the plurality of the output stages 6₁ to 6ₙ being configured in step S404.

In step S404, the pulse is transmitted via the pulse line 31 to each output stage 6₁ to 6ₙ for rerouting based on the output stage configuration.

The logic processing unit 10 may determine the appropriate configuration for the demultiplexers 5₁ to 5ₙ depending on the desired pulse path and direction. This information regarding appropriate configuration is sent through the respective communication lines 51₁ to 51ₙ to the demultiplexers 5₁ to 5ₙ. The demultiplexers 5₁ to 5ₙ may interpret and configure a respective output stage of the output stages 6₁ to 6ₙ to the appropriate state via respective selection lines 61₁ to 61ₙ. The states of an output stage are explained in detail above with respect to FIG. 4.

In step S405, the pulse waveform is generated.

Such a pulse waveform may be generated by the pulse generator 3.

The output stage configuration is explained above with respect to step S403 as well as above with respect to FIGS. 4 and 5.

In step S407, the pulse is transmitted via the pulse line 31 to each output stage 6₁ to 6ₙ for rerouting based on the output stage configuration ..

In step S406, the measured pulse waveform is monitored by the real time feedback 4, which gives feedback to the pulse waveform generator 3, enabling generation of a desired waveform.

The measuring (e.g., monitoring, etc.) of the pulse waveform by the feedback circuitry 4 is explained in detail above

In step S411, the real time feedback sends back the pulse measurements to the output feedback, which is used to diagnose the state of the actuator.

The state of the actuator may be determined based on the pulse waveform as explained in detail above with respect to FIG. 3.

In step S408, the routing process is performed.

The routing process is explained above with respect to FIG. 5.

The pulse parameters are monitored by the safety protections in step S409 which can stop or modify the pulse generation if the safety parameters are exceeded.

The monitoring is explained in detail above with respect to the safety protection circuitry 7.

In step S410, the pulse is transmitted to the output connector which delivers the pulse to the load.

It is noted that any of the steps described above may be included as code instructions in a program, which may be executed by one or more processors. For example, the logic processing unit 10 in FIG. 1 may include one or more processors or processing circuitries.

The methodologies described herein may be implemented by various means depending upon the application. For example, these methodologies may be implemented in hardware, operation system, firmware, software, or any combination of two or all of them. For a hardware implementation, any processing circuitry may be used, which may include one or more processors. For example, the hardware may include one or more of application specific integrated circuits (ASICs), digital signal processors (DSPs), digital signal processing devices (DSPDs), programmable logic devices (PLDs), field programmable gate arrays (FPGAs), processors, controllers, any electronic devices, or other electronic circuitry units or elements designed to perform the functions described above.

If implemented as program code, the functions performed by the transmitting apparatus (device) may be stored as one or more instructions or code on a non-transitory computer readable storage medium such as a memory or any other type of storage. The computer-readable media includes physical computer storage media, which may be any available medium that can be accessed by the computer, or, in general by a processing circuitry. Such computer-readable media may comprise RAM, ROM, EEPROM, optical disk storage, magnetic disk storage, semiconductor storage, or other storage devices. Some particular and non-limiting examples include compact disc (CD), CD-ROM, laser disc, optical disc, digital versatile disc (DVD), Blu-ray (BD) disc or the like. Combinations of different storage media are also possible—in other words, distributed and heterogeneous storage may be employed.

Embodiments or aspects and exemplary implementations mentioned above show some non-limiting examples. It is understood that various modifications may be made without departing from the claimed subject matter. For example, modifications may be made to adapt the examples to new systems and scenarios without departing from the central concept described herein.

### EXAMPLES

According to some non-limiting embodiments or aspects, a cryogenic actuator controller is provided, the cryogenic actuator controller comprising: a pulse generator 3 for generating a plurality of pulses 31; a feedback circuitry 4 for measuring and controlling at least one of a power, a voltage, and/or a current of the plurality of pulses 31; at least one output stage 6 for selecting a plurality of paths 71₁ to 71ₙ and directing the plurality of pulses 31 to the plurality of paths 71₁ to 71ₙ; at least one demultiplexer 5 for controlling the at least one output stage 6; and/or a safety protection circuitry 7 for monitoring and protecting a cryogenic load and one or more cryogenic components.

In some implementations, the pulse generator 3 generates a plurality of energy-limited pulses 31 by controlling or restricting at least one of a voltage, a current, a duration, and/or a frequency of the plurality of energy-limited pulses.

For example, the feedback circuitry 4 determines the state of the cryogenic actuator state based on features of a measured waveform.

In some implementations, the pulse generator 3 controls the energy of the plurality of pulses 31 independent of an impedance of the cryogenic load.

For example, the safety protection circuitry 7 monitors at least one of an output voltage, an output current, and/or a pulse waveform duration of the plurality of the pulses 31.

In some implementations, the safety protection circuitry 7 comprises one or a plurality of independent sections.

For example, at least one output stage 6₁ to 6ₙ may be adaptable and operable to select one or more paths or directions for the power pulse to be delivered to the load.

According to some non-limiting embodiments or aspects, provided is a method for controlling a level of energy input to a cryogenic load, the method including: generating a plurality of pulses 31 of electrical energy; monitoring at least one of a power, a voltage, and/or a current of the plurality of pulses 31; selecting one or more paths of a plurality of paths 71₁ to 71ₙ to provide one or more pulses of the plurality of pulses 31 to a plurality of cryogenic loads in a cryostat; and monitoring a cryogenic load and one or more cryogenic components of the cryostat.

In some implementations, the method is further includes dynamically modulating one or more of an applied current 42 and/or an applied voltage 41 of pulses of the plurality of pulses 31 to obtain a given pulse waveform.

For example, the selecting of the one or more paths of the plurality of paths 71₁ to 71ₙ may be dynamic and independently selectable.

In some implementations, the selecting of the one or more paths of the plurality of paths 711 to 71n enables different pulses of the plurality of pulses 31 to be supplied to different loads of the plurality of cryogenic loads.

For example, the method may further include recording a pulse of the plurality of pulses 31 to enable dynamic state estimation of the cryogenic load.

In some implementations, the method further includes computing and controlling the energy delivered to the cryogenic load.

For example, the method may further include controlling or limiting of the energy delivered to the cryogenic load for controlling or limiting the power dissipated inside the cryostat.

Accordingly, non-limiting embodiments or aspects of the present disclosure may provide a cryogenic actuator controller and method for operating the cryogenic actuator controller. The cryogenic actuator controller may include a pulse generator 3 for generating a plurality of pulses 31, a feedback circuitry 4 for measuring at least one of a power, a voltage, and/or a current of the plurality of pulses 31, at least one output stage 6 for selecting a plurality of paths 61₁ to 61ₙ and directing the plurality of pulses 31 to the plurality of paths 61₁ to 61ₙ, at least one demultiplexer 5 for controlling the at least one output stage 6, and/or a safety protection circuitry 7 for monitoring and protecting a cryogenic load and one or more cryogenic components 14.

1. A cryogenic actuator controller comprising:
a pulse generator configured to generate a plurality of pulses;
a feedback circuitry configured to measure and control at least one of a power of the plus of pulses, a voltage of the plurality of pulses, a current of the plurality of pulses, or any combination thereof;
at least one output stage configured to select one or more paths of a plurality of paths and direct one more pulses of the plurality of pulses to the one or more paths of the plurality of paths;
at least one demultiplexer configured to control the at least one output stage; and
a safety protection circuitry configured to monitor and protect a cryogenic load and one or more cryogenic components.

2. The cryogenic actuator controller of claim 1, wherein the pulse generator is configured to generate the plurality of pulses as a plurality of energy-limited pulses by controlling at least one of the voltage of the plurality of pulses, the current of the plurality pulses, a duration of the plurality of pulses, a frequency of the plurality of energy pulses, or any combination thereof.

3. The cryogenic actuator controller of claim 1, wherein the feedback circuitry is configured to determine a state of the cryogenic actuator based on features of a measured waveform associated with the plurality of pulses.

4. The cryogenic actuator controller of claim 1, wherein the pulse generator is configured to control an energy level of the plurality of pulses independent of an impedance of the cryogenic load.

5. The cryogenic actuator controller of claim 1, wherein the safety protection circuitry is configured to monitor at least one of an output voltage of the plurality of the pulses, an output current of the plurality of the pulses, a pulse waveform duration of the plurality of the pulses of the plurality of the pulses, or any combination thereof.

6. The cryogenic actuator controller of claim 1, wherein the safety protection circuitry includes one or more independent sections.

7. The cryogenic actuator controller of claim 1, wherein the at least one output stage is configured to dynamically and independently select the one or more paths of the plurality of paths for the one or more pulses of the plurality of pulses to be delivered to the cryogenic load.

8. A method for controlling a level of energy input to a cryogenic load comprising:
generating a plurality of pulses of electrical energy;
monitoring at least one of a power of the plurality of pulses, a voltage of the plurality of pulses, a current of the plurality of pulses, or any combination thereof;
selecting one or more paths of a plurality of paths to provide one or more pulses of the plurality of pulses to one or more cryogenic loads of a plurality of cryogenic loads in a cryostat; and
monitoring the one or more cryogenic loads of the plurality of cryogenic loads and one or more cryogenic components of the cryostat.

9. The method of claim 8, further comprising:
dynamically modulating one or more of an applied current of the plurality of pulses, an applied voltage of the plurality of pulses, or any combination thereof to obtain a given pulse waveform.

10. The method of claim 8, wherein the one or more paths of the plurality of paths are dynamically and independently selected.

11. The method of claim 8, wherein selecting the one or more paths of the plurality of paths supplies different pulses of the plurality of pulses to different loads of the plurality of cryogenic loads.

12. The method of claim 8, further comprising:
recording a pulse of the plurality of pulses to enable a dynamic state estimation of the cryogenic load.

13. The method of claim 8, further comprising:
computing and controlling the level of energy delivered to the cryogenic load.

14. The method of claim 13, further comprising:
controlling the energy delivered to the cryogenic load to control an amount of power dissipated inside the cryostat.
